(19) United States
(12) Patent Application Publication
(10) Pub. No.: US 2006/0226434 A1
(43) Pub. Date: Oct. 12, 2006

(54) Nitride-based semiconductor light emitting device and manufacturing method thereof

(75) Inventor: Toshio Hata, Mihara-shi (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka-shi (JP)

(21) Appl. No.: 11/403,511

(22) Filed: Apr. 12, 2006

(30) Foreign Application Priority Data
Apr. 12, 2005 (JP) JP2005-114386
Feb. 20, 2006 (JP) JP2006-042630

(51) Int. Cl. H01L 33/00

(52) U.S. Cl. 257/94

(57) ABSTRACT

A present nitride-based semiconductor light emitting device includes: a pattern surface formed on a conductive substrate; a multilayered metal layer formed on the pattern surface; and a multilayered semiconductor layer formed on the multilayered metal layer, and characterized in that main surfaces of the multilayered metal layer and the multilayered semiconductor layer have smaller area than the pattern surface has, and the multilayered semiconductor layer includes a p type nitride-based semiconductor layer, a light emitting layer and an n type nitride-based semiconductor layer. Thus, a highly reliable nitride-based semiconductor light emitting device with excellent adhesion between a nitride-based semiconductor layer and a conductive substrate, and a manufacturing method thereof are provided.

This nonprovisional application is based on Japanese Patent Applications Nos. 2005-114386 and 2006-042630 filed with the Japan Patent Office on Apr. 12, 2005 and Feb. 20, 2006, respectively, the entire contents of which are hereby incorporated by reference.

### BACKGROUND OF THE INVENTION

1. Field of the Invention

The present invention relates to a nitride-based semiconductor light emitting device such as a semiconductor laser diode or a light emitting diode and to a manufacturing method thereof, and particularly to a manufacturing method of a nitride-based semiconductor light emitting device including a step of bonding a patterned conductive substrate and a multilayered semiconductor layer including a nitride-based semiconductor layer and to a nitride-based semiconductor light emitting device obtained by the manufacturing method.

2. Description of the Background Art

A conventional nitride-based semiconductor light emitting device is formed as shown in FIG. 8 for example, wherein on a conductive substrate 100 having a positive electrode 107 formed on its back surface, a first ohmic electrode 101 and a second ohmic electrode 102 are formed. A p type layer 103, an active layer (light emitting layer) 104, and an n type layer 105 each made of nitride-based semiconductor are successively formed on second ohmic electrode 102, and a negative electrode 106 is formed on n type layer 105. It is proposed that this nitride-based semiconductor light emitting device 80 may be manufactured by bonding first ohmic electrode 101 and second ohmic electrode 102 together by hot pressure bonding (for example, see Japanese Patent Laying-Open No. 09-008403).

According to Japanese Patent Laying-Open No. 09-008403, the ohmic electrode is formed on the conductive substrate, and the entire surface of the conductive substrate and that of the nitride-based semiconductor layer are bonded together using schemes such as hot pressure bonding. However, since the entire surface of the conductive substrate of a large area and the entire surface of the nitride-based semiconductor layer are bonded together via the ohmic electrode and bonding metal, it has been difficult to apply uniform heating and pressure bonding. As such, there has been a problem that the entire surface of the nitride-based semiconductor layer may peel off from the conductive substrate due to poor adhesion therebetween.

If the ohmic electrode and the bonding metal are separated from the conductive substrate completely, it is not possible to remove a sapphire substrate used as a base substrate, which hinders formation of a nitride-based semiconductor light emitting device having electrodes on both main surfaces. There has been a problem that, if the conductive substrate and the nitride-based semiconductor layer are partially peeled off from each other, flow of the current from the nitride-based semiconductor layer to the conductive substrate is hindered, increasing operating voltage, whereby reliability of the nitride-based semiconductor light emitting device is impaired. There has been a problem that this partial peeling leads to entire peeling of the conductive substrate and the nitride-based semiconductor layer from each other upon cutting the wafer into chips, whereby the yield of the manufacturing process is reduced. Further, solvent, resist, or etchant during the process infiltrates into the partially peeled-off portion, thereby aggravating the peeling to destroy the ohmic electrode and the bonding electrode. Thus, there has been a problem that the reliability of the nitride-based semiconductor light emitting device is impaired.

### SUMMARY OF THE INVENTION

An object of the present invention is to provide a highly reliable nitride-based semiconductor light emitting device with excellent adhesion between a nitride-based semiconductor layer and a conductive substrate, and a manufacturing method thereof The present invention is directed to a nitride-based semiconductor light emitting device, including: a pattern surface formed on a conductive substrate; a multilayered metal layer formed on the pattern surface; and a multilayered semiconductor layer formed on the multilayered metal layer, wherein a main surface of the multilayered metal layer and a main surface of the multilayered semiconductor layer have smaller area than the pattern surface has, and the multilayered semiconductor layer includes a p type nitride-based semiconductor layer, a light emitting layer and an n type nitride-based semiconductor layer.

In the nitride-based semiconductor light emitting device according to the present invention, a side surface of the light emitting layer may be formed along a surface including a side surface of the multilayered metal layer and a side surface of the multilayered semiconductor layer. Further, the conductive substrate may be formed by at least one selected from the group consisting of Si, GaAs, GaP, InP, and Ge, and may have a convex pattern surface. Still further, a base substrate may be stacked on the multilayered semiconductor layer directly or via an intermediate layer, and the base substrate may be formed by at least one selected from the group consisting of sapphire, spinel, lithium niobate, SiC, Si, ZnO, and GaAs. Still further, the intermediate layer may be a nitride-based buffer layer. Still further, the nitride-based buffer layer may have conductivity. Still further, to the nitride-based buffer layer, at least 10¹³ cm⁻³ and at most 10²⁰ cm⁻³ of Si may be added as dopant.

The present invention is also directed to A manufacturing method of a nitride-based semiconductor light emitting device, comprising the steps of forming, on a base substrate directly or via an intermediate layer, a multilayered semiconductor layer including an n type nitride-based semiconductor layer, a light emitting layer and a p type nitride-based semiconductor layer, and forming a semiconductor-side multilayered metal layer on the multilayered semiconductor layer; forming a pattern surface on a conductive substrate, and forming on the pattern surface a substrate-side multilayered metal layer having a main surface that has smaller area than the pattern surface has; and bonding the semiconductor-side multilayered metal layer and the substrate-side multilayered metal layer so that respective bonding metal layers are joined.

In the manufacturing method of a nitride-based semiconductor light emitting device according to the present invention, the base substrate may be formed by at least one selected from the group consisting of sapphire, spinel, lithium niobate, SiC, Si, ZnO, and GaAs. Further, the intermediate layer may be a nitride-based buffer layer. Still further, the nitride-based buffer layer may have conductivity. Still further, to the nitride-based buffer layer, at least 10¹³ cm⁻³ and at most 10²⁰ cm⁻³ of Si may be added as dopant. Still further, in the step of bonding the semiconductor-side multilayered metal layer and the substrate-side multilayered metal layer, respective bonding metal layers may be joined using eutectic bonding for metal. Still further, in the step of bonding the semiconductor-side multilayered metal layer and the substrate-side multilayered metal layer, respective bonding metal layers may be joined using room temperature bonding for metal.

The manufacturing method of a nitride-based semiconductor light emitting device according to the present invention may further include a base substrate separating step of separating the base substrate from the multilayered semiconductor layer. The manufacturing method may further include an unbonded region separating step of separating a region in the multilayered semiconductor layer and the semiconductor-side multilayered metal layer to which the substrate-side multilayered metal layer is not bonded from a region in the multilayered semiconductor layer and the semiconductor-side multilayered metal layer to which the substrate-side multilayered metal layer is bonded. Here, the base substrate separating step and the unbonded region separating step may be performed simultaneously. For example, the base substrate separating step and the unbonded region separating step may be performed simultaneously by applying laser light irradiation from a base substrate side. The manufacturing step may further include a step of providing a scribe line from a back surface of the conductive substrate opposite to a pattern groove formed in the conductive substrate to divide the conductive substrate into chips.

According to the present invention, a highly reliable light emitting device where adhesion between the nitride-based semiconductor layer and the conductive substrate is high and a manufacturing method thereof can be provided.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-sectional view showing a step of forming a multilayered semiconductor layer and a semiconductor-side multilayered metal layer.

FIG. 2 is a schematic cross-sectional view showing a step of forming a pattern of a conductive substrate and a step of forming a substrate-side multilayered metal layer.

FIG. 3 is a schematic cross-sectional view showing a step of bonding the semiconductor-side multilayered metal layer and the substrate-side multilayered metal layer.

FIG. 4 is a schematic cross-sectional view showing a step of separating a base substrate and a step of separating a region in the multilayered semiconductor layer and the semiconductor-side multilayered metal layer to which the substrate-side multilayered metal layer is not bonded.

FIG. 5 is a schematic cross-sectional view showing a step of forming an electrode and a step of cutting into chips.

FIG. 6 is a schematic cross-sectional view showing one embodiment of a nitride-based semiconductor light emitting device according to the present invention.

FIG. 7 is a schematic cross-sectional view showing another embodiment of a nitride-based semiconductor light emitting device according to the present invention.

FIG. 8 is a schematic cross-sectional view showing a conventional nitride-based semiconductor light emitting device.

### DESCRIPTION OF THE PREFERRED EMBODIMENTS

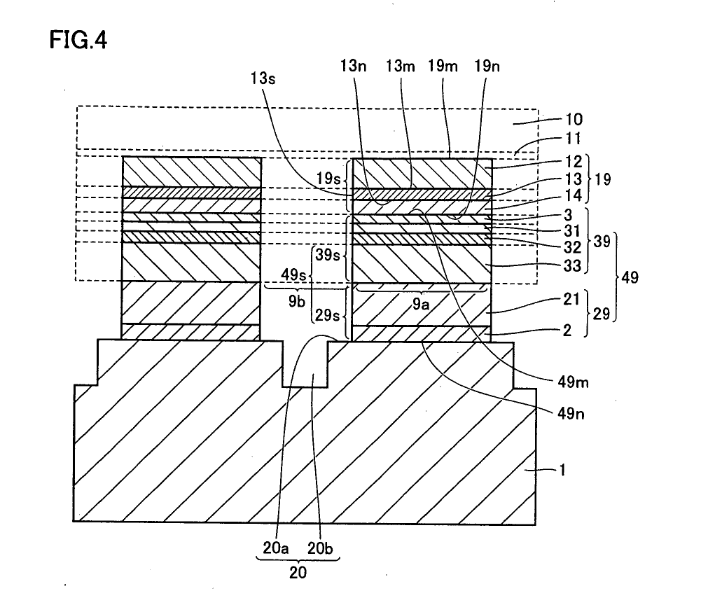

A nitride-based semiconductor light emitting device according to the present invention includes, for example referring to FIGS. 4-7, a pattern surface 20a formed on a conductive substrate 1, a multilayered metal layer 49 formed thereon, and a multilayered semiconductor layer 19 formed thereon, being characterized in that main surfaces 49m, 49n, 19m, and 19n of multilayered metal layer 49 and multilayered semiconductor layer 19 have smaller area than pattern surface 20a has, and that multilayered semiconductor layer 19 includes a p type nitride-based semiconductor layer 14, a light emitting layer 13 and an n type nitride-based semiconductor layer 12.

As multilayered metal layer 49 and multilayered semiconductor layer 19 (including p type nitride-based semiconductor layer 14, light emitting layer 13 and n type nitride-based semiconductor layer 12) having main surfaces 49m and 49n and main surfaces 19m and 19n having smaller area than pattern surface 20a has, respectively, are formed, a light emitting device can be obtained that has an excellent light emitting surface pattern, without peeling between conductive substrate 1 and multilayered semiconductor layer 19 including the nitride-based semiconductor layer, and that has a high light output. Additionally, by using conductive substrate 1, electrodes can be formed on main surfaces of the both sides of the light emitting device. The nitride-based semiconductor refers to a semiconductor including a nitride semiconductor, and for example includes InₓAl_{y}Ga_{1-x-y}N (0<x, 0<y, x+y≦1).

In the nitride-based semiconductor light emitting device according to the present invention, referring to FIGS. 4-7, it is preferable that a side surface 13s of light emitting layer 13 is formed along a surface including a side surface 49s of multilayered metal layer 49 and a side surface 19s of multilayered semiconductor layer 19. That is, it is preferable that multilayered semiconductor layer 19 having main surfaces 19m and 19n including light emitting layer 13 having main surfaces 13m and 13n is formed within and on the entire surface of one main surface 49m of multilayered metal layer 49. With light emitting layer 13 formed in such a manner, main surfaces 13m and 13n of light emitting layer 13 attains substantially the same shape and the same area as main surfaces 49m and 49n of multilayered metal layer 49 and main surfaces of 19m and 19n of multilayered semiconductor layer 19, and thus a nitride-based semiconductor light emitting device with excellent luminous efficacy can be obtained.

In the nitride-based semiconductor light emitting device according to the present invention, it is preferable that conductive substrate 1 is formed by at least one selected from the group consisting of Si, GaAs, GaP, InP, and Ge, and has a convex pattern surface 20a. As conductive substrate 1, using such a substrate of which difference from the multilayered semiconductor layer including the nitride-based semiconductor layer in thermal expansion coefficient is small, a nitride-based semiconductor light emitting device with less warp can be obtained;

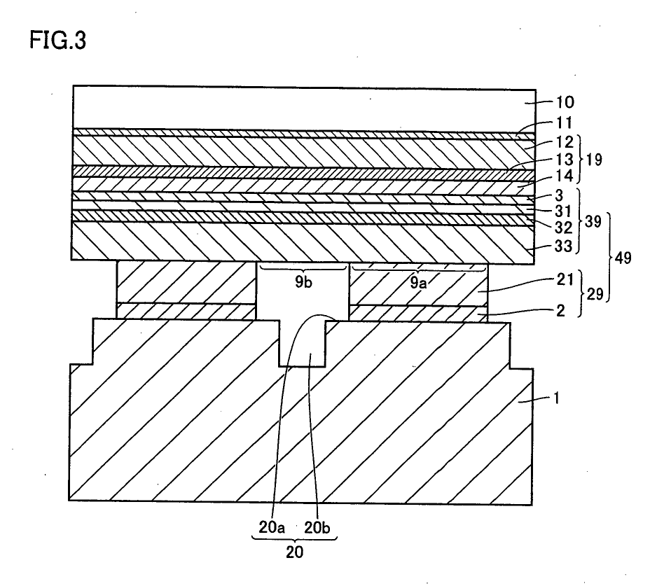

Further, referring to FIG. 3, it is preferable that the nitride-based semiconductor light emitting device according to the present invention includes a base substrate 10 on multilayered semiconductor layer 19 directly or via an intermediate layer 11, wherein base substrate 10 is formed by at least one selected from the group consisting of sapphire, spinel, lithium niobate, SiC, Si, ZnO, and GaAs. Using the base substrate formed by at least one selected from the group consisting of sapphire, spinel, lithium niobate, SiC, Si, ZnO, and GaAs, multilayered semiconductor layer 19 with an excellent crystallinity is formed, and a highly reliable light emitting device with a high light output can be obtained. In particular, using Si as the base substrate, an inexpensive light emitting device can be obtained.

Still further, referring to FIG. 3, in an intermediate nitride-based semiconductor light emitting device in one step of manufacturing the final nitride-based semiconductor light emitting device according to the present invention, it is preferable that intermediate layer 11 is a nitride-based buffer layer. Forming the nitride-based buffer layer (intermediate layer 11) between base substrate 10 and multilayered semiconductor layer 19, multilayered semiconductor layer 19 having further excellent crystallinity is formed, and a further highly reliable light emitting device with further high light output can be obtained. Still further, it is preferable that the nitride-based buffer layer has conductivity. Thus the ohmic contact in the later step is facilitated wherein base substrate 10 is separated from multilayered semiconductor layer 19 and an ohmic electrode is formed on multilayered semiconductor layer 19. Still further it is preferable that, to the nitride-based buffer layer, at least 10¹³ cm⁻³ and at most 10²⁰ cm⁻³ of Si is added as dopant. If the Si dopant amount is less than 10¹³ cm⁻³, the nitride-based buffer layer will not show conductivity (n type conductivity). If the Si dopant amount is more than 10²⁰ cm⁻³, the nitride-based buffer layer will not attain two-dimensional growth (which, throughout the following description, refers to the growth toward parallel direction relative to the main surface of the substrate) and attains three-dimensional growth (which, throughout the following description, refers to the growth toward perpendicular direction relative to the main surface of the substrate), and thus the crystallinity of multilayered semiconductor layer 19 is deteriorated. Considering the above, it is more preferable that the dopant amount of Si is at least 10¹⁶ cm⁻³ and at most 10²⁰ cm⁻³.

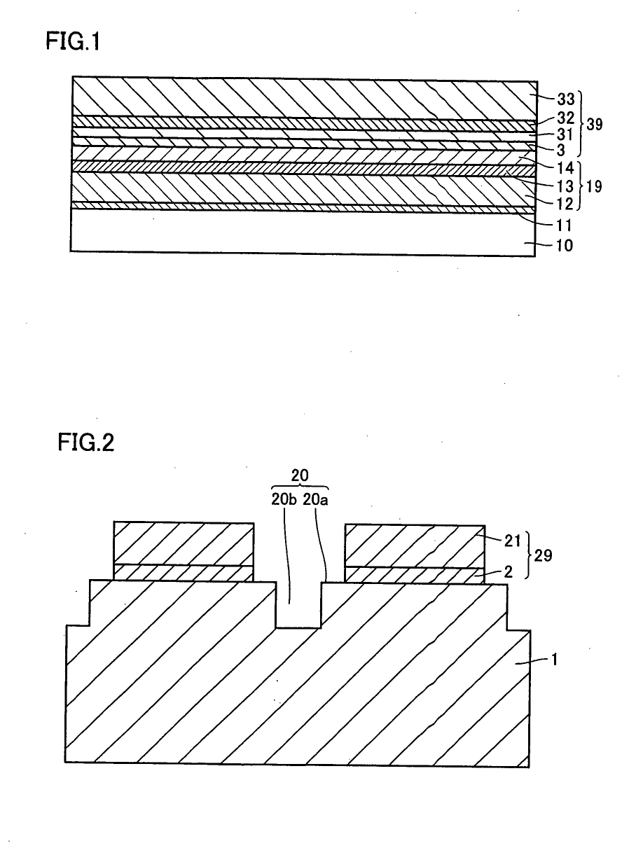

Referring to FIGS. 1-3, a manufacturing method of a nitride-based semiconductor light emitting device according to the present invention includes the steps of: forming, on a base substrate 10 directly or via an intermediate layer 11, a multilayered semiconductor layer 19 including an n type nitride-based semiconductor layer 12, a light emitting layer 13 and a p type nitride-based semiconductor layer 14, and forming a semiconductor-side multilayered metal layer 39 on multilayered semiconductor layer 19; forming a pattern surface 20a on a conductive substrate 1, and forming on pattern surface 20a a substrate-side multilayered metal layer 29 having a main surface that has smaller area than pattern surface 20a has; and bonding semiconductor-side multilayered metal layer 39 and substrate-side multilayered metal layer 29 so that respective bonding metal layers 33 and 21 are joined.

Bonding substrate-side multilayered metal layer 29 having a main surface that has smaller area than pattern surface 20a has and semiconductor-side multilayered metal layer 39 so that respective bonding metal layers 21 and 33 are joined, the region to which the substrate-side multilayered metal layer is bonded (bonding region 9a in FIG. 3) can uniformly be joined without partial peeling.

In the manufacturing method of a nitride-based semiconductor light emitting device according to the present invention, it is preferable that base substrate 10 is formed by at least one selected from the group consisting of sapphire, spinel, lithium niobate, SiC, Si, ZnO, and GaAs. Using the base substrate formed by at least one selected from the group consisting of sapphire, spinel, lithium niobate, SiC, Si, ZnO, and GaAs, multilayered semiconductor layer 19 with excellent crystallinity is formed, and a highly reliable light emitting device with a high light output can be manufactured. In particular, using Si as the base substrate, an inexpensive light emitting device can be manufactured.

In the manufacturing method of a nitride-based semiconductor light emitting device according to the present invention, it is preferable that intermediate layer 11 is a nitride-based buffer layer. Forming the nitride-based buffer layer (intermediate layer 11) on base substrate 10 and forming multilayered semiconductor layer 19 thereon, multilayered semiconductor layer 19 having further excellent crystallinity is formed, and a further highly reliable light emitting device with further high light output can be manufactured. Further, providing nitride-based buffer layer (intermediate layer 11) between base substrate 10 and multilayered semiconductor layer 19, separation of multilayered semiconductor layer 19 from base substrate 10 in the later step can be facilitated.

In the manufacturing method of a nitride-based semiconductor light emitting device according to the present invention, it is preferable that the nitride-based buffer layer has conductivity. The ohmic contact in the later step is facilitated wherein base substrate 10 is separated from multilayered semiconductor layer 19 and an ohmic electrode is formed on multilayered semiconductor layer 19.

In the manufacturing method of a nitride-based semiconductor light emitting device according to the present invention, it is preferable that, to the nitride-based buffer layer, at least 10¹³ cm⁻³ and at most 10²⁰ cm⁻³ of Si is added as dopant. If the Si dopant amount is less than 10¹³ cm⁻³, the nitride-based buffer layer will not show conductivity (n type conductivity). If the Si dopant amount is more than 10²⁰ cm⁻³, the nitride-based buffer layer will not attain two-dimensional growth and attains three-dimensional growth, and thus the crystallinity of multilayered semiconductor layer 19 is deteriorated.

Referring to FIG. 3, in the step of bonding semiconductor-side multilayered metal layer 39 and substrate-side multilayered metal layer 29 in the manufacturing method of a nitride-based semiconductor light emitting device according to the present invention, it is preferable to join respective bonding metal layers 33 and 21 using eutectic bonding for metal. Here, eutectic bonding for metal refers to bonding method wherein other metal is joined and heated whereby solid phase is attained near the temperature specific to the other metal. Using eutectic bonding for metal, the temperature at which bonding is carried out can be set to at most 300° C., and joining with high adhesion can be attained without impairing the ohmic characteristics of ohmic electrodes 2 and 3 and reflection characteristics of reflection metal layer 31.

Referring to FIG. 3, in the step of bonding semiconductor-side multilayered metal layer 39 and substrate-side multilayered metal layer 29 in the manufacturing method of a nitride-based semiconductor light emitting device according to the present invention, it is preferable to join respective bonding metal layers 33 and 21 using room temperature bonding for metal. Here, room temperature bonding refers to a method wherein surfaces to be bonded are activated by plasma processing or etching processing by argon ions or the like and bonded. Using room temperature bonding for metal, the temperature at which bonding is carried out can be set to the room temperature (for example about 10° C.-30° C.) and joining with high adhesion can be attained without impairing the ohmic characteristics of ohmic electrodes 2 and 3 and reflection characteristics of reflection metal layer 31. Thus, a highly reliable light emitting device can be manufactured.

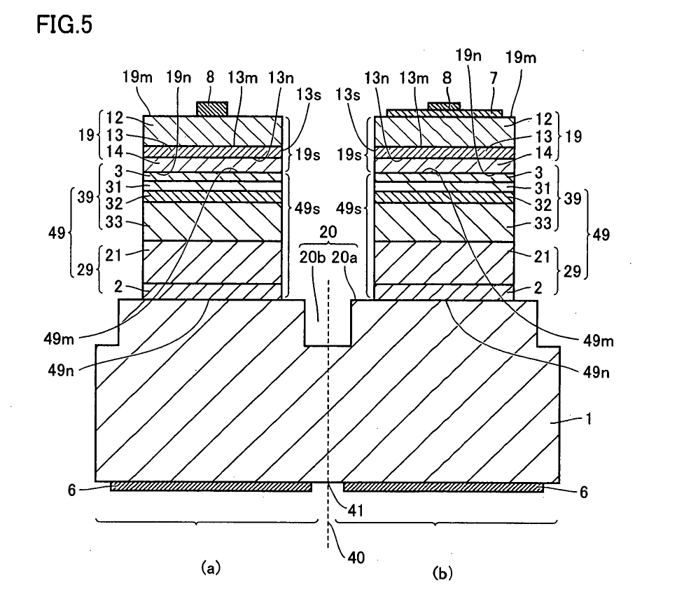

Referring to FIG. 4, it is preferable that the manufacturing method of a nitride-based semiconductor light emitting device according to the present invention further includes a base substrate separating step of separating base substrate 10 from multilayered semiconductor layer 19. Separating base substrate 10 from multilayered semiconductor layer 19, one main surface 19m of multilayered semiconductor layer 19 can be exposed. In a later step (for example as in FIG. 5), forming one electrode on this one main surface 19m and forming the other electrode on conductive substrate 1, the highly reliable light emitting element having electrodes on both main surfaces can be obtained. Here, the method of separating base substrate 10 from multilayered semiconductor layer 19 includes, in addition to use of laser light, wet etching, dry etching and the like.

Referring to FIG. 4, it is preferable that the manufacturing method of a nitride-based semiconductor light emitting device according to the present invention further includes an unbonded region separating step of separating a region in multilayered semiconductor layer 19 and semiconductor-side multilayered metal layer 39 to which substrate-side multilayered metal layer 29 is not bonded (hereinafter referred to as unbonded region 9b) from a region in multilayered semiconductor layer 19 and semiconductor-side multilayered metal layer 39 to which substrate-side multilayered metal layer 29 is bonded (hereinafter referred to as bonded region 9a). Separating unbonded region 9b from bonded region 9a in multilayered semiconductor layer 19 and semiconductor-side multilayered metal layer 39, a highly reliable light emitting device having a patterned light emitting surface can be manufactured. Here, the method for separating unbonded region 9b from bonded region 9a includes, in addition to use of laser light, wet etching, dry etching and the like.

Referring to FIG. 4, in the manufacturing method of a nitride-based semiconductor light emitting device according to the present invention, it is preferable that the base substrate separating step and the unbonded region separating step are performed simultaneously. The base substrate separating step and the unbonded region separating step being performed simultaneously can achieve efficient manufacture of a highly reliable light emitting device having a patterned light emitting surface. As base substrate 10 is separated, unbonded region 9b becomes a thin layer formed by multilayered semiconductor layer 19 and semiconductor-side multilayered metal layer 39 not supported by the substrate, and thus can extremely easily be separated from bonded region 9a formed by multilayered semiconductor layer 19 and semiconductor-side multilayered metal layer 39 supported by conductive substrate 1. Here, although the method for simultaneously performing the base substrate separating step and the unbonded region separating step is not specifically limited, in the light of efficiently manufacturing a highly reliable light emitting element having a patterned light emitting surface, it is preferable to apply laser light irradiation from the base substrate 10 side. That is, applying laser light irradiation from base substrate 10 side, separation of base substrate 10 from multilayered semiconductor layer 19 is facilitated. Additionally, use of laser light enables separation of unbonded region 9b from bonded region 9a without dry etching, wet etching or the like, whereby a highly reliable light emitting device having main surfaces 13m and 13n (which are to be the light emitting surfaces) of light emitting layer 13 of multilayered semiconductor layer within and on the entire bonded region 9a can efficiently be manufactured.

Referring to FIG. 5, it is preferable that the manufacturing method of a nitride-based semiconductor light emitting device according to the present invention further includes a step of providing a scribe line 41 from the back surface of conductive substrate 1 opposite to a pattern groove 20b formed in conductive substrate 1 to divide conductive substrate 1 into chips. Thus, conductive substrate 1 can be divided into chips without damaging multilayered semiconductor layer 19, and in particular to light emitting layer 13. The method for providing the scribe line from the back surface of the conductive substrate includes, for example, a method of applying laser light irradiation from the back surface of the conductive substrate, and a method of mechanically providing the line on the back surface of the conductive substrate using a diamond needle or the like.

In the following, the nitride-based semiconductor light emitting device and the manufacturing method thereof according to the present invention will be described in further detail.

### First Embodiment

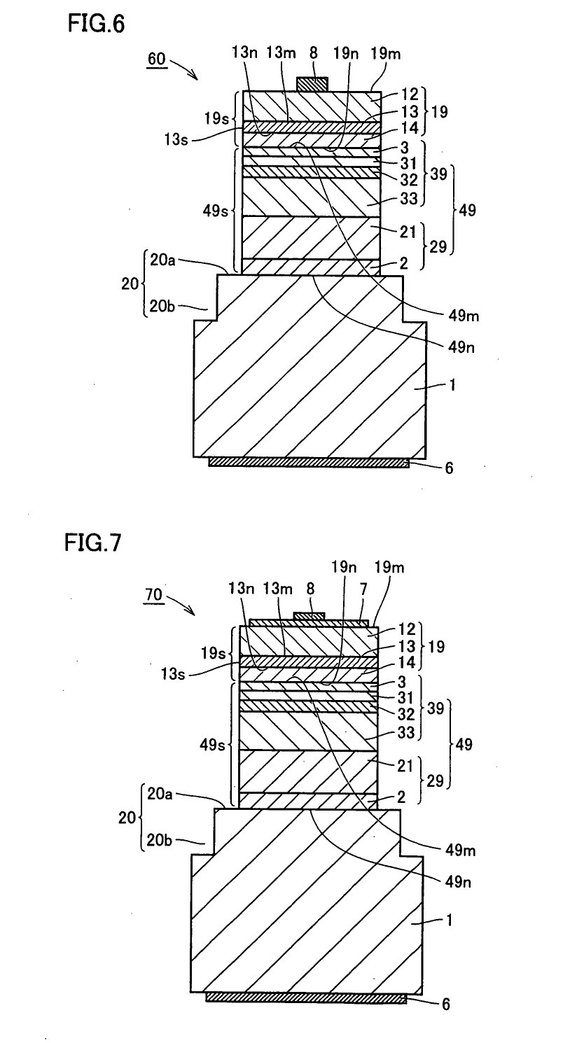

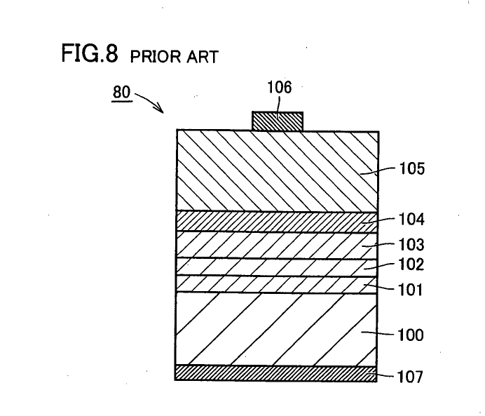

Referring to FIG. 6, a nitride-based semiconductor light emitting device 60 in an embodiment of the present invention has a pattern surface 20a formed on an Si substrate serving as conductive substrate 1, on which a multilayered metal layer 49 and a multilayered semiconductor layer 19 having main surfaces 49m, 49n, 19m, and 1 9n having smaller area than pattern surface 20a has are formed. Here, multilayered metal layer 49 is constituted by a substrate-side multilayered metal layer 29 including an ohmic electrode 2 and a bonding metal layer 21 formed on pattern surface 20a of conductive substrate 1, and a semiconductor-side multilayered metal layer 39 including a bonding metal layer 33, a barrier layer 32, a reflection metal layer 31 and an ohmic electrode 3, wherein bonding metal layer 21 of substrate-side multilayered metal layer 29 and bonding metal layer 33 of semiconductor-side multilayered metal layer 39 are joined. On ohmic electrode 3 of semiconductor-side multilayered metal layer 39, a multilayered semiconductor layer 19 including a p type nitride-based semiconductor layer 14, a light emitting layer 13 and an n type nitride-based semiconductor layer 12 is formed. On n type nitride-based semiconductor layer 12 of multilayered semiconductor layer 19, a semiconductor-side pad electrode 8 is formed, and a substrate-side electrode 6 is formed on a back main surface of the Si substrate serving as conductive substrate 1.

The nitride-based semiconductor light emitting device in the present embodiment is manufactured through the following manufacturing steps. First, referring to FIG. 1, on a sapphire substrate serving as base substrate 10, an Si dope GaN buffer layer of a 20 nm thickness as intermediate layer 11, and as multilayered semiconductor layer 19, an n type GaN layer of a 5 μm thickness serving as n type nitride-based semiconductor layer 12, an MQW (Multi-Quantum Well) light emitting layer of a 50 nm thickness serving as light emitting layer 13, and a p type GaN layer of a 150 nm thickness serving as p type nitride-based semiconductor layer 14 are successively grown (multilayered semiconductor layer forming step). Here, intermediate layer 11 and multilayered semiconductor layer 19 are both grown using MOCVD (Metal-Organic Chemical Vapor Deposition).

Next, referring to FIG. 1, on p type nitride-based semiconductor layer 14, as semiconductor-side multilayered metal layer 39, a Pd layer of 3 nm thickness serving as ohmic electrode 3, an Ag—Nd layer of 150 nm thickness serving as reflection metal layer 31, an Ni—Ti layer of 150 nm thickness serving as a barrier layer 32, and a composite layer of Au layer (0.5 μm thickness)/AuSn layer (3 μm thickness)/Au layer (10 nm thickness) serving as bonding metal 33 are formed by EB (Electron Beam deposition) (semiconductor-side multilayered metal layer forming step). Here, Sn is contained in the AuSn layer by 20 mass %. The Au layer of 10 nm thickness serves as an antioxidant layer of the AuSn layer.

Referring to FIG. 2, on the Si substrate serving as conductive substrate 1, using fluorine-based etching liquid, pattern 20 having a pattern groove 20b of 50 μm width and 10 μm depth and a square pattern surface 20a of each side being 300 μm is formed (pattern forming step). Next, as substrate-side multilayered metal layer 29 having main surfaces having smaller area than pattern surface 20a has, on pattern surface 20a of the Si substrate having been patterned, a composite layer of Ti layer (15 nm thickness)/Al layer (150 nm thickness) serving as ohmic electrode 2 and a composite layer of Au layer (0.5 μm thickness)/AuSn layer (3 μm thickness)/Au layer (10 nm thickness) serving as bonding metal layer 21 are formed in this order by EB (substrate-side multilayered metal layer forming step).

Next, referring to FIG. 3, semiconductor-side multilayered metal layer 39 and substrate-side multilayered metal layer 29 are bonded so that respective bonding metal layers 33 and 21 are joined, using eutectic bonding at an ambient temperature of 300° C. and under a pressure of 300 N/cm² (bonding step).

Next, referring to FIG. 4, irradiation of YAG-THG laser (wavelength 355 nm) is applied from the sapphire substrate side being mirror-polished, to attain pyrolysis of the Si dope GaN buffer layer serving as intermediate layer 11 and part of the n type GaN layer serving as n type nitride-based semiconductor layer 12, whereby the sapphire substrate (base substrate 10) is separated from multilayered semiconductor layer 19 and unbonded region 9b is peeled off from bonded region 9a and separated. That is, the base substrate 10 separating step and unbonded region 9b separating step are performed simultaneously. Thus, a nitride-based semiconductor light emitting device can be obtained, wherein side surface 13s of light emitting layer 13 is formed along a surface including side surface 49s of multilayered metal layer 49 (that is, side surface 29s of substrate-side multilayered metal layer 29 and side surface 39s of semiconductor-side multilayered metal layer 39) and a side surface 19s of multilayered semiconductor layer 19. The nitride-based semiconductor light emitting device is patterned so that light emitting layer 13 of multilayered semiconductor layer 19 has the light emitting surface only in bonded region 9a.

Next, referring to FIG. 5(a), an n type bonding pad electrode serving as semiconductor-side pad electrode 8 is formed at a central portion on an n type GaN layer serving as n type nitride-based semiconductor layer 12 to be the light emitting surface exposed by removal of the sapphire substrate serving as base substrate 10. On the back side of the Si substrate serving as conductive substrate 1, a composite layer of Ti layer (15 nm thickness)/Al layer (150 nm thickness)/Ti layer (15 nm thickness) serving as substrate-side electrode 6 is formed by deposition. After deposition, heat treatment is applied to the device at 300° C.

Further, applying laser light irradiation on a dividing line 40 along pattern groove 20b from the back surface of the Si substrate serving as conductive substrate 1, a scribe line 41 is formed. Breaking along the dividing line, the Si substrate is divided into chips of square of each side being 350 μm (chipping step). Thus, nitride-based semiconductor light emitting device 60 in the present embodiment shown in FIG. 6 is obtained.

According to the nitride-based semiconductor light emitting device in the present embodiment, after bonding the semiconductor-side multilayered metal layer formed on the multilayered semiconductor layer and the substrate-side multilayered metal layer formed on the pattern surface of the conductive substrate, separating a region in the multilayered semiconductor layer and the semiconductor-side multilayered metal layer to which the substrate-side multilayered metal layer is not bonded (unbonded region), a highly reliable light emitting device having a patterned light emitting surface can be obtained, where the multilayered semiconductor layer and the conductive substrate are uniformly adhered.

Additionally, as the nitride-based semiconductor light emitting device in the present embodiment has the multilayered semiconductor layer and the conductive substrate being uniformly adhered, the light emitting surface formed by the multilayered semiconductor layer is prevented from peeling off, and the leakage current decreases also. Further, according to the present nitride-based semiconductor light emitting device, as the scribe line is provided from the back surface of the conductive substrate along the pattern groove of the conductive substrate so that the substrate is divided into chips, the side surface of the multilayered semiconductor layer will not be scribed and the leakage current is decreased. Further, employing the manufacturing method of the present embodiment, separation of the nitride-based semiconductor layer having the light emitting surface is facilitated, and therefore the highly reliable nitride-based semiconductor light emitting device can be manufactured in lower costs.

### Second Embodiment

Referring to FIG. 7, a nitride-based semiconductor light emitting device 70 in another embodiment of the present invention has a pattern surface 20a formed on an Si substrate serving as conductive substrate 1, on which a multilayered metal layer 49 and a multilayered semiconductor layer 19 having main surfaces 49m, 49n, 19m, and 19n having smaller area than pattern surface 20a has are formed. Here, multilayered metal layer 49 is constituted by a substrate-side multilayered metal layer 29 including an ohmic electrode 2 and a bonding metal layer 21 formed on pattern surface 20a of conductive substrate 1, and a semiconductor-side multilayered metal layer 39 including a bonding metal layer 33, a barrier layer 32, a reflection metal layer 3 1 and a ohmic electrode 3, wherein bonding metal layer 21 of substrate-side multilayered metal layer 29 and bonding metal layer 33 of semiconductor-side multilayered metal layer 39 are joined. On ohmic electrode 3 of semiconductor-side multilayered metal layer 39, a multilayered semiconductor layer 19 including a p type nitride-based semiconductor layer 14, a light emitting layer 13 and an n type nitride-based semiconductor layer 12 is formed. On n type nitride-based semiconductor layer 12 of multilayered semiconductor layer 19, a semiconductor-side electrode 7 and a semiconductor-side pad electrode 8 are formed, and a substrate-side electrode 6 is formed on a back main surface of the Si substrate serving as conductive substrate 1.

The nitride-based semiconductor light emitting device in the present embodiment is manufactured through the following manufacturing steps. First, referring to FIG. 1, on a sapphire substrate serving as base substrate 10, an Si dope GaN buffer layer of a 20 nm thickness as intermediate layer 11, and as multilayered semiconductor layer 19, an n type GaN layer of a 5 μm thickness serving as n type nitride-based semiconductor layer 12, an MQW (Multi-Quantum Well) light emitting layer of a 50 nm thickness serving as light emitting layer 13, and a p type GaN layer of a 150 nm thickness serving as p type nitride-based semiconductor layer 14 are successively grown (multilayered semiconductor layer forming step). Here, intermediate layer 11 and multilayered semiconductor layer 19 are both grown using MOCVD (Metal-Organic Chemical Vapor Deposition).

Next, referring to FIG. 1, on p type nitride-based semiconductor layer 14, as semiconductor-side multilayered metal layer 39, a Pd layer of 3 nm thickness serving as ohmic electrode 3, an Ag—Bi layer of 20 nm thickness serving as reflection metal layer 31, an Mo layer of 60 nm thickness serving as a barrier layer 32, and a composite layer of Au layer (0.5 μm thickness)/AuSn layer (3 μm thickness)/Au layer (10 nm thickness) serving as bonding metal 33 are formed by EB (Electron Beam deposition) (semiconductor-side multilayered metal layer forming step). Here, Sn is contained in the AuSn layer by 20 mass %. The Au layer of 10 nm thickness serves as an antioxidant layer of the AuSn layer.

Referring to FIG. 2, on the Si substrate serving as conductive substrate 1, using fluorine-based etching liquid, pattern 20 having a pattern groove 20b of 50 μm width and 10 μm depth and a square pattern surface 20a of each side being 200 μm is formed (pattern forming step). Next, as substrate-side multilayered metal layer 29 having main surfaces having smaller area than pattern surface 20a has, on pattern surface 20a of the Si substrate having been patterned, a composite layer of Ti layer (15 nm thickness)/Al layer (150 nm thickness) serving as ohmic electrode 2 and a composite layer of Au layer (0.5 μm thickness)/AuSn layer (3 μm thickness)/Au layer (10 nm thickness) serving as bonding metal layer 21 are formed in this order by EB (substrate-side multilayered metal layer forming step).

Next, referring to FIG. 3, semiconductor-side multilayered metal layer 39 and substrate-side multilayered metal layer 29 are bonded so that respective bonding metal layers 33 and 21 are joined, using room temperature bonding at a room temperature (for example 20° C.) (bonding step).

Next, referring to FIG. 4, irradiation of YAG-THG laser (wavelength 355 nm) is applied from the sapphire substrate side being mirror-polished, to attain pyrolysis of the Si dope GaN buffer layer serving as intermediate layer 11 and part of the n type GaN layer serving as n type nitride-based semiconductor layer 12, whereby the sapphire substrate (base substrate 10) is separated from multilayered semiconductor layer 19 and unbonded region 9b is peeled off from bonded region 9a and separated. That is, the base substrate 10 separating step and unbonded region 9b separating step are performed simultaneously. Thus, a nitride-based semiconductor light emitting device can be obtained, wherein side surface 13s of light emitting layer 13 is formed along a surface including side surface 49s of multilayered metal layer 49 (that is, side surface 29s of substrate-side multilayered metal layer 29 and side surface 39s of semiconductor-side multilayered metal layer 39) and a side surface 19s of multilayered semiconductor layer 19. The nitride-based semiconductor light emitting device is patterned so that light emitting layer 13 of multilayered semiconductor layer 19 has the light emitting surface only in bonded region 9a.

Next, referring to FIG. 5(b), a transparent electrode of ITO (In₂O₃) layer serving as semiconductor-side electrode 7 is formed on an n type GaN layer serving as n type nitride-based semiconductor layer 12 to be the light emitting surface exposed by removal of the sapphire substrate serving as base substrate 10, and an n type bonding pad electrode serving as semiconductor-side pad electrode 8 is formed at the central portion of the transparent electrode. On the back side of the Si substrate serving as conductive substrate 1, a composite layer of Ti layer (20 nm thickness)/Al layer (200 nm thickness) serving as substrate-side electrode 6 is formed by deposition. After deposition, heat treatment is applied to the device at 300° C. Although in the present embodiment the transparent electrode (semiconductor-side electrode 7) is formed substantially entirely on n type nitride-based semiconductor layer 12, it may be a branched type transparent electrode. Alternatively, an n type bonding pad electrode may be formed on the n type nitride-based semiconductor layer without providing the transparent electrode.

Further, applying laser light irradiation on a dividing line 40 along pattern groove 20b from the back surface of the Si substrate serving as conductive substrate 1, a scribe line 41 is formed. Breaking along the dividing line, the Si substrate is divided into chips of square of each side being 250 μm (chipping step). Thus, nitride-based semiconductor light emitting device 70 in the present embodiment shown in FIG. 7 is obtained.

According to the nitride-based semiconductor light emitting device in the present embodiment, after bonding the semiconductor-side multilayered metal layer formed on the multilayered semiconductor layer and the substrate-side multilayered metal layer formed on the pattern surface of the conductive substrate, separating a region in the multilayered semiconductor layer and the semiconductor-side multilayered metal layer to which the substrate-side multilayered metal layer is not bonded (unbonded region), a highly reliable light emitting device having a patterned light emitting surface can be obtained, where the multilayered semiconductor layer and the conductive substrate are uniformly adhered. In particular, according to the present embodiment, as bonding (joining) of the semiconductor-side multilayered metal layer and the substrate-side multilayered metal layer are performed at a room temperature, the light emitting layer is not damaged and unevenness in the emission wavelength is eliminated, and the change in the emission wavelength after joining is reduced. Further, warp in the conductive substrate and the base substrate after joining is reduced.

Additionally, as the nitride-based semiconductor light emitting device in the present embodiment has the multilayered semiconductor layer and the conductive substrate being uniformly adhered, the light emitting surface formed by the multilayered semiconductor layer is prevented from peeling off, and the leakage current decreases also. Further, according to the present nitride-based semiconductor light emitting device, as the scribe line is provided from the back surface of the conductive substrate along the pattern groove of the conductive substrate so that the substrate is divided into chips, the side surface of the multilayered semiconductor layer will not be scribed and the leakage current is decreased. Further, employing the manufacturing method of the present embodiment, separation of the nitride-based semiconductor layer having the light emitting surface is facilitated, and therefore the highly reliable nitride-based semiconductor light emitting device can be manufactured in lower costs.

As above, the nitride-based semiconductor light emitting device of the present invention is manufactured, after bonding the semiconductor-side multilayered metal layer formed on the multilayered semiconductor layer and the substrate-side multilayered metal layer formed on the pattern surface of the conductive substrate, by separating a region in the multilayered semiconductor layer and the semiconductor-side multilayered metal layer to which the substrate-side multilayered metal layer is not bonded (unbonded region). Therefore, a highly reliable light emitting device having a patterned light emitting surface where the multilayered semiconductor layer and the conductive substrate are uniformly adhered can be obtained easily, cost-effectively and in high yield. Further, as the semiconductor-side multilayered metal layer formed on the multilayered semiconductor layer and the substrate-side multilayered metal layer formed on the pattern surface of the conductive substrate are bonded, the area to which the substrate-side multilayered metal layer is bonded (bonded region) is small, whereby warp of the bonded conductive substrate and the base substrate is reduced.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A nitride-based semiconductor light emitting device, comprising:
a pattern surface formed on a conductive substrate;
a multilayered metal layer formed on said pattern surface; and
a multilayered semiconductor layer formed on said multilayered metal layer, wherein
a main surface of said multilayered metal layer and a main surface of said multilayered semiconductor layer have smaller area than said pattern surface has, and
said multilayered semiconductor layer includes a p type nitride-based semiconductor layer, a light emitting layer and an n type nitride-based semiconductor layer.

2. The nitride-based semiconductor light emitting device according to claim 1, wherein
a side surface of said light emitting layer is formed along a surface including a side surface of said multilayered metal layer and a side surface of said multilayered semiconductor layer.

3. The nitride-based semiconductor light emitting device according to claim 1, wherein
said conductive substrate is formed by at least one selected from the group consisting of Si, GaAs, GaP, InP, and Ge, and has a convex pattern surface.

4. The nitride-based semiconductor light emitting device according to claim 1, wherein
a base substrate is stacked on said multilayered semiconductor layer directly or via an intermediate layer, and
said base substrate is formed by at least one selected from the group consisting of sapphire, spinel, lithium niobate, SiC, Si, ZnO, and GaAs.

5. The nitride-based semiconductor light emitting device according to claim 4, wherein
said intermediate layer is a nitride-based buffer layer.

6. The nitride-based semiconductor light emitting device according to claim 5, wherein
said nitride-based buffer layer has conductivity.

7. The nitride-based semiconductor light emitting device according to claim 5, wherein
to said nitride-based buffer layer, at least 10¹³ cm⁻³ and at most 10²⁰ cm⁻³ of Si is added as dopant.

8. A manufacturing method of a nitride-based semiconductor light emitting device, comprising the steps of:
forming, on a base substrate directly or via an intermediate layer, a multilayered semiconductor layer including an n type nitride-based semiconductor layer, a light emitting layer and a p type nitride-based semiconductor layer, and forming a semiconductor-side multilayered metal layer on said multilayered semiconductor layer;
forming a pattern surface on a conductive substrate, and forming on said pattern surface a substrate-side multilayered metal layer having a main surface that has smaller area than said pattern surface has; and
bonding said semiconductor-side multilayered metal layer and said substrate-side multilayered metal layer so that respective bonding metal layers are joined.

9. The manufacturing method of a nitride-based semiconductor light emitting device according to claim 8, wherein
said base substrate is formed by at least one selected from the group consisting of sapphire, spinel, lithium niobate, SiC, Si, ZnO, and GaAs.

10. The manufacturing method of a nitride-based semiconductor light emitting device according to claim 8, wherein
said intermediate layer is a nitride-based buffer layer.

11. The manufacturing method of a nitride-based semiconductor light emitting device according to claim 10, wherein
said nitride-based buffer layer has conductivity.

12. The manufacturing method of a nitride-based semiconductor light emitting device according to claim 10, wherein
to said nitride-based buffer layer, at least 10¹³ cm⁻³ and at most 10²⁰ cm⁻³ of Si is added as dopant.

13. The manufacturing method of a nitride-based semiconductor light emitting device according to claim 8, wherein
in said step of bonding said semiconductor-side multilayered metal layer and said substrate-side multilayered metal layer, respective bonding metal layers are joined using eutectic bonding for metal.

14. The manufacturing method of a nitride-based semiconductor light emitting device according to claim 8, wherein
in said step of bonding said semiconductor-side multilayered metal layer and said substrate-side multilayered metal layer, respective bonding metal layers are joined using room temperature bonding for metal.

15. The manufacturing method of a nitride-based semiconductor light emitting device according to claim 8, further comprising
a base substrate separating step of separating said base substrate from said multilayered semiconductor layer.

16. The manufacturing method of a nitride-based semiconductor light emitting device according to claim 15, further comprising
an unbonded region separating step of separating a region in said multilayered semiconductor layer and said semiconductor-side multilayered metal layer to which said substrate-side multilayered metal layer is not bonded from a region in said multilayered semiconductor layer and said semiconductor-side multilayered metal layer to which said substrate-side multilayered metal layer is bonded.

17. The manufacturing method of a nitride-based semiconductor light emitting device according to claim 16, wherein
said base substrate separating step and said unbonded region separating step are performed simultaneously.

18. The manufacturing method of a nitride-based semiconductor light emitting device according to claim 17, wherein
said base substrate separating step and said unbonded region separating step are performed simultaneously by applying laser light irradiation from a base substrate side.

19. The manufacturing method of a nitride-based semiconductor light emitting device according to claim 8, further comprising a step of
providing a scribe line from a back surface of said conductive substrate opposite to a pattern groove formed in said conductive substrate to divide said conductive substrate into chips.
